(19) United States
(12) Patent Application Publication
(10) Pub. No.: US 2025/0048670 A1
(43) Pub. Date: Feb. 6, 2025

(54) METHOD FOR PRODUCING A POWER FINFET, AND POWER FINFET

(71) Applicant: Robert Bosch GmbH, Stuttgart (DE)

(72) Inventors: Daniel Krebs, Aufhausen (DE); Alberto Martinez-Limia, Pliezhausen (DE); Jens Baringhaus, Sindelfingen (DE)

(21) Appl. No.: 18/716,636

(22) PCT Filed: Dec. 14, 2022
(86) PCT No.: PCT/EP2022/085802

§ 371 Date: Jul. 16, 2024

(30) Foreign Application Priority Data
Dec. 15, 2021 (DE) 10 2021 214 431.4

(51) Int. Cl. H01L 29/78; H01L 21/311; H01L 21/3115; H01L 29/06; H01L 29/16; H01L 29/20; H01L 29/66

(52) U.S. Cl. CPC H01L 29/785; H01L 21/31116; H01L 21/31144; H01L 21/31155; H01L 29/0665; H01L 29/1608; H01L 29/2003; H01L 29/66734; H01L 29/66795; H01L 29/7813

(57) ABSTRACT

A power finFET. The power finFET has two-part control electrodes and a semiconductor body which has a drift layer, and a second connection region arranged above the drift layer. The first trenches and second trenches extend from the second connection region into the drift layer, and being arranged in an alternating manner, the second trenches having a smaller width than the first trenches. Shielding zones are arranged below the first trenches, the shielding zones directly adjoining the first trenches, and the shielding zones being connected to source regions in an electrically conductive manner. A two-part control electrode is arranged within the first trenches in each case, the two-part control electrode being electrically insulated from the shielding zone below the first trenches in each case. Fins are arranged between the first trenches and the second trenches, the fins having a width of at most 500 nm.

### FIELD

The present invention relates to a method for producing a power finFET having two-part control electrodes and to a power finFET having two-part control electrodes.

### BACKGROUND INFORMATION

In power electronics, semiconductors with a wide band gap such as SiC or GaN are used. Typically, power MOSFETs having a vertical channel zone are used.

To increase the breakdown voltage of such power MOSFETs, shielding zones are arranged below the trenches. Since these shielding zones are connected to the source regions, it is necessary to arrange two-part control electrodes within the trenches, as described in German Patent No. DE 10224201 B4.

A disadvantage here is that the trenches have to be very wide, so the pitch dimension and the on-resistance of the power MOSFET are large.

Between the shielding zones, which are usually p-doped, a so-called JFET is formed between two adjacent trenches, which serves to limit the current through the channel zone in the event of a short circuit. For this purpose, p-doped shielding zones are implanted using a lithographically structured mask.

The disadvantage here is that the gaps between two p-doped shielding zones are thereby exposed to process fluctuations that affect the limitation of the short-circuit current.

An object of the present invention is to overcome these disadvantages.

### BRIEF DESCRIPTION OF THE DRAWINGS

A method according to an example embodiment of the present invention for producing a power finFET having two-part control electrodes and a semiconductor body which has a second connection region and a drift layer, wherein the second connection region forms a front side of the semiconductor body, comprises: producing a first structured mask on the front side of the semiconductor body by means of a lithography step, wherein the first mask has oxide regions and first open regions, wherein the first open regions expose the front side of the semiconductor body; and producing first trenches below the first open regions by means of a first etching process starting from the front side of the semiconductor body into the drift layer. Furthermore, the method comprises producing shielding zones below the first trenches by means of a first implantation process, and applying a polysilicon layer to the front side of the semiconductor body so that the first trenches are filled. The method comprises: applying an isotropic oxide layer to the front side of the semiconductor body; producing a second structured mask by means of a second etching process so that the isotropic oxide layer has second open regions, wherein the second open regions expose the front side of the semiconductor body; and producing second trenches below the second open regions by means of a third etching process starting from the front side into the drift layer, wherein the second trenches are arranged substantially in parallel with the first trenches, and the first trenches and the second trenches alternate, wherein the second trenches have a smaller width than the first trenches. The method further comprises oxidizing the front side so that a further oxide layer is arranged on the front side, and widening the first trenches and the second trenches by means of a fourth etching process so that fins are produced between the first trenches and the second trenches, wherein the fins have a width of less than 500 nm. The method comprises activating the shielding zones by means of annealing, and producing two-part control electrodes within the first trenches.

An advantage here is that the short-circuit current-limiting effect occurs between the shielding zone and the side walls of the second trenches. This allows process fluctuations to be tolerated.

In a development of the present invention, the first structured mask has nitride regions, wherein the oxide regions are arranged on the nitride regions.

An advantage here is that oxidation of the fin top is prevented.

In a further embodiment, spreading zones below the second trenches are produced by means of a second implantation process, wherein the second implantation energy has a value between 200 keV and 2500 keV.

An advantage here is that the on-resistance is low.

In a development, the first etching process, the second etching process and the third etching process are anisotropic plasma etching processes.

An advantage here is that the structured masks can be transferred to the underlying layers with minimal widening.

In one example embodiment of the present invention, the first implantation process has a first implantation energy in the range of 30 keV to 2700 keV.

An advantage here is that the shielding zones are produced in the trench bottom below the gate oxide to be protected, so that a maximum shielding effect is achieved without pitch loss.

According to an example embodiment of the present invention, the power finFET having two-part control electrodes has a semiconductor body with a drift layer and a second connection region. The second connection region is arranged above the drift layer, and first trenches and second trenches extend from the second connection region into the drift layer. First trenches and second trenches are arranged in an alternating manner, wherein the second trenches have a smaller width than the first trenches, and shielding zones are arranged below the first trenches. The shielding zones directly adjoin the first trenches, and the shielding zones are connected to source regions in an electrically conductive manner. A two-part control electrode is arranged within the first trenches in each case, and the two-part control electrode is electrically insulated from the shielding zone below the first trenches in each case. According to the present invention, fins are arranged between the first trenches and the second trenches, the fins having a width of maximally 500 nm.

An advantage here is that the short-circuit current is limited by the space-charge zone of the shielding zones and of the opposite trench wall of a second trench. Furthermore, it is advantageous that the influence of process variability on the short-circuit current and the on-resistance is reduced.

In a development of the present invention, spreading zones are arranged below the second trenches.

An advantage here is that the current propagation is high and the on-resistance is low.

In a further embodiment of the present invention, the shielding zones are p-doped and have a dopant concentration of at least 1E18/cm³.

The advantage here is that high implantation doses can be introduced cost-effectively below the trench bottom.

In one example embodiment of the present invention, the semiconductor body comprises SiC.

An advantage here is that aluminum, which is easily activated, can be used for implantation.

In a further embodiment of the present invention, the semiconductor body comprises GaN.

An advantage here is that the critical field strength and the electron mobility are high.

Further advantages of the present invention can be found in the following description of exemplary embodiments and the rest of the disclosure herein.

### BRIEF DESCRIPTION OF EXAMPLE EMBODIMENTS

The present invention is explained below with reference to preferred embodiments and the figures.

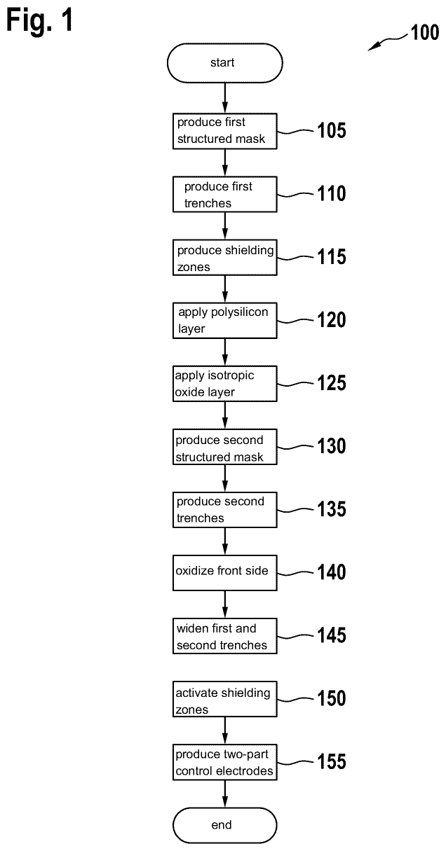

FIG. 1 shows a method for producing a power finFET with two-part control electrodes, according to an example embodiment of the present invention.

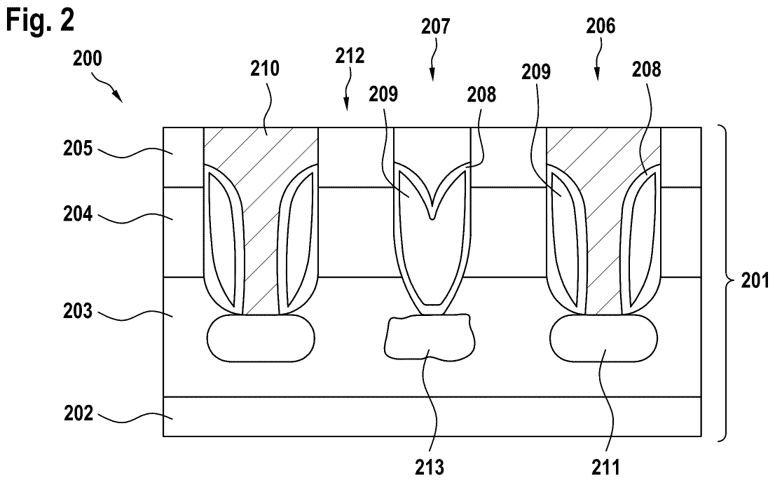

FIG. 2 shows a power finFET with two-part control electrodes, according to an example embodiment of the present invention.

### DETAILED DESCRIPTION OF EXAMPLE EMBODIMENTS

FIG. 1 shows a method for producing a power finFET with two-part control electrodes. The power finFET comprises a semiconductor body, which comprises, for example, SiC or GaN, a second connection region and a drift layer, wherein the second connection region forms a front side of the semiconductor body. The method starts with step 105, in which a first structured mask is produced on the front side of the semiconductor body by means of a lithography step. The first structured mask has oxide regions and first open regions that expose the front side of the semiconductor body. In a subsequent step 110, first trenches are produced below the first open regions by means of a first etching process, starting from the front side of the semiconductor body into the drift layer. In a subsequent step 115, shielding zones are produced below the first trenches by means of a first implantation process with a first implantation energy. The first implantation energy is between 30 keV and 2700 keV. The shielding zones are p-doped. In a subsequent step 120, a polysilicon layer is applied to the front side of the semiconductor body so that the first trenches are filled. In a subsequent step 125, an isotropic oxide layer is applied to the front side of the semiconductor body. In a subsequent step 130, a second structured mask is produced by means of a second etching process, so that the isotropic oxide layer has second open regions, wherein the second open regions expose the front side of the semiconductor body. In a subsequent step 135, second trenches are produced below the second open regions by means of a third etching process, starting from the front side of the semiconductor body into the drift layer. The second trenches are arranged parallel to the first trenches and alternate, the second trenches having a smaller width than the first trenches. In other words, a self-aligned or self-adjusted mask is produced in step 130. As a result, in step 135, the second trenches can be produced sublithographically by means of a mask reversal process, and the width of the mesas between the first trenches and the second trenches or the pitch can be determined by the thickness of the isotropic oxide layer. Furthermore, a precise adjustment between the shielding zones below the first trenches and the opposite side walls of the second trenches is possible, so that an optimal setting of the on-resistance, the short-circuit current and the field in the oxide of the trench bottom of the second trenches can be realized. In a subsequent step 140, the front side of the semiconductor body is oxidized so that a further oxide layer is arranged on the front side of the semiconductor body. The further oxide layer has a thickness of at least 10 nm. In a subsequent step 145, the first trenches and the second trenches are widened by means of a fourth etching process, so that fins having a width of less than 500 nm are produced between the first trenches and the second trenches. The oxide from step 140 is selectively etched wet-chemically. Steps 140 and 145 are carried out cyclically depending on the fin width to be achieved. In other words, the front side of the semiconductor body is oxidized multiple times, with an etching step taking place between the oxidation steps. The widening of the trenches thus occurs without adjustment, since the lateral oxidation rate exceeds the vertical oxidation rate by approximately a factor of two. In a subsequent step 150, the shielding zones are activated by annealing. The annealing is typically carried out at 1700° C. In a subsequent step 155, the two-part control electrodes are produced within the first trenches.

With the aid of the method according to the present invention, the shielding zones below the first trenches are further apart from one another than the shielding zones are from the opposite trench walls or side walls of the second trenches. As a result, the short-circuit current is not limited by the collision of the space-charge zones of two shielding zones, but by the space-charge zone of each p-doped shielding zone, which displaces or pushes the current against the opposite trench wall of a second trench. The low sensitivity to process variability is achieved by the fact that, in the event of a short circuit, the trench wall of the second trench forms an accumulation channel due to the positive gate voltage, which accumulation channel cannot be cleared by the space-charge zone of the p-doped shielding zone.

The first etching process, the second etching process and the third etching process are anisotropic etching processes. The fourth etching process is isotropic. In the case of a SiC semiconductor body, the first and third etching processes select between SiC, which is etched, and SiO2, SiN and Si, which are not etched. In the case of a SiC semiconductor body, the second etching process and the fourth etching process select between SiO2, which is etched, and SiC, SiN and Si, which are not etched.

In an exemplary embodiment, the first structured mask has nitride regions, which are located between the front side and the oxide regions. The nitride regions protect the front side or surface of the fins, since oxidation of the fin top is prevented in this way in step 140. The nitride regions are removed in an intermediate step, not shown in FIG. 1, between step 145 and step 150.

In a further exemplary embodiment, spreading zones are implanted below the second trenches by means of a second implantation process. The spreading zones are n-doped and have a higher doping than the n-doped drift layer. This increases the current propagation effect below the second trenches. The second implantation process has a second implantation energy that has a value between 200 keV and 2500 keV.

FIG. 2 shows a power finFET 200 with two-part control electrodes 209. The power finFET 200 has a semiconductor body 201 that has a first connection region 202, a drift layer 203, a channel zone 204 and a second connection region 205. The first connection region 202 acts as a drain connection, and the second connection region 205 acts as a source connection. The drift layer 203 is arranged on the first connection region 202, the channel zone 204 is arranged on the drift layer 203, and the second connection region 202 is arranged on the channel zone 204. The second connection region 202 acts as the front side of the semiconductor body 201. Starting from the front side of the semiconductor body 201, first trenches 206 and second trenches 207 extend into the drift layer 203, wherein the second trenches 207 have a smaller width than the first trenches 206. The first trenches 206 and the second trenches 207 are arranged in an alternating manner. Shielding zones 211, which are preferably p-doped, are arranged below the first trenches 206 and directly adjoin a trench bottom of the first trenches 206. The dopant concentration of the shielding zones 211 is at least 1E18/cm³. The shielding zones 211 are connected in an electrically conductive manner to source regions 210 arranged within the trenches. A two-part control electrode 209, which acts as a gate connection, is arranged within each first trench 206. The two-part control electrode 209 is electrically insulated from the shielding zone 211 by means of an oxide layer 208. Between the first trenches 206 and the second trenches 207, fins 212 are arranged which have a width of less than 500 nm.

The semiconductor body 201 comprises SiC or GaN.

In one exemplary embodiment, spreading zones 213 are arranged below the second trenches 207. The spreading zones 213 are n-doped and have a higher doping than the drift layer 203, which is also n-doped.

The power finFET is used in DC/DC converters and inverters of an electric drive train of electric or hybrid vehicles, as well as in vehicle chargers.

1-10. (canceled)

11. A method for producing a power finFET having two-part control electrodes, wherein the power finFET includes a semiconductor body which has a second connection region and a drift layer, wherein the second connection region forms a front side of the semiconductor body, the method comprising the following steps:
producing a first structured mask on the front side of the semiconductor body using a lithography step, wherein the first structured mask has oxide regions and first open regions, wherein the first open regions expose the front side of the semiconductor body;
producing first trenches below the first open regions using a first etching process, starting from the front side of the semiconductor body into the drift layer;
producing shielding zones below the first trenches using a first implantation process;
applying a polysilicon layer to the front side of the semiconductor body so that the first trenches are filled;
applying an isotropic oxide layer to the front side of the semiconductor body;
producing a second structured mask using a second etching process, so that the isotropic oxide layer has second open regions, and the second open regions expose the front side of the semiconductor body;
producing second trenches below the second open regions using a third etching process, starting from the front side into the drift layer, wherein the second trenches are arranged substantially in parallel with the first trenches, and the first trenches and the second trenches alternate, wherein the second trenches have a smaller width than the first trenches;
oxidizing the front side so that a further oxide layer is arranged on the front side;
widening the first trenches and the second trenches using a fourth etching process so that fins are produced between the first trenches and the second trenches, wherein the fins have a width of less than 500 nm;
activating the shielding zones using annealing; and
producing the two-part control electrodes within the first trenches.

12. The method according to claim 11, wherein the first structured mask has nitride regions, the oxide regions being arranged on the nitride regions.

13. The method according to claim 11, wherein spreading zones are produced below the second trenches using a second implantation process, a second implantation energy of the second implantation process having a value of between 200 keV and 2500 keV.

14. The method according to claim 11, wherein the first etching process, the second etching process, and the third etching process are anisotropic plasma etching processes.

15. The method according to claim 11, wherein the first implantation process has a first implantation energy in a range of 30 keV to 2700 keV.

16. A power finFET having two-part control electrodes and a semiconductor body, the power finFET comprising:
a drift layer; and
a second connection region, the second connection region being arranged above the drift layer, and first trenches and second trenches extending from the second connection region into the drift layer, the first trenches and the second trenches being arranged in an alternating manner, the second trenches having a smaller width than the first trenches, shielding zones being arranged below the first trenches, the shielding zones directly adjoining the first trenches, and the shielding zones being connected to source regions in an electrically conductive manner, a two-part control electrode being arranged within each of the first trenches, and each two-part control electrode being electrically insulated from the shielding zone below the first trenches in each case, wherein fins are arranged between the first trenches and the second trenches, the fins having a width of at most 500 nm.

17. The power finFET according to claim 16, wherein spreading zones are arranged below the second trenches.

18. The power finFET according to claim 16, ehrtrin the shielding zones are p-doped and have a dopant concentration of at least 1E18/cm³.

19. The power finFET according to claim 16, wherein the semiconductor body includes SiC.

20. The power finFET according to claim 16, wherein the semiconductor body includes GaN.
